(19) United States
(12) Patent Application Publication
(10) Pub. No.: US 2005/0109533 A1
(43) Pub. Date: May 26, 2005

(54) Circuit board and manufacturing method thereof that can easily provide insulating film between projecting electrodes

(75) Inventors: Mamoru Kurashina, Kawasaki (JP); Yoshikatsu Ishizuki, Kawasaki (JP); Nawalage Florence Cooray, Kawasaki (JP); Masataka Mizukoshi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/023,012

(22) Filed: Dec. 28, 2004

Related U.S. Application Data
(63) Continuation of application No. PCT/JP03/04572, filed on Apr. 10, 2003.

(30) Foreign Application Priority Data
Aug. 27, 2002 (JP) 2002-246837

(51) Int. Cl. H05K 1/03; H05K 1/11

(52) U.S. Cl. 174/255; 174/258; 174/264

(57) ABSTRACT

A manufacturing method of a circuit board includes the steps of: forming projecting electrodes on a substrate; forming a photosensitive resin film on the substrate so as to cover the projecting electrodes; exposing a substantially entire surface of the photosensitive film; and melting the surface of the photosensitive film so as to expose the projecting electrodes.

### CROSS-REFERENCE TO RELATED APPLICATION

This application is a U.S. continuation application, filed under 35 USC 111(a) and claiming the benefit under 35 USC 120 and 365(c), of PCT application PCT/JP2003/004572, filed Apr. 10, 2003, which claims priority to Application Ser. No. 2002-246837, filed in Japan on Aug. 27, 2002. The foregoing applications are hereby incorporated herein by reference.

### BACKGROUND OF THE INVENTION

1. Field of the Invention

The present invention generally relates to circuit boards, and more particularly, to a manufacturing method of a circuit board carrying projecting electrodes and an insulating layer around the projecting electrodes.

2. Description of the Related Art

Generally, built-up substrates, MCM substrates, interposers, printed-circuit boards and the like are formed by multi-layer circuit boards. Varnish materials used in processes of multi-layer circuit boards include photosensitive varnish materials and non-photosensitive varnish materials.

Processes using a photosensitive varnish material include a process called MCM-D wherein, after forming photo vias, wiring is formed by a sputtering method and an electrolytic plating method. In the process, a photosensitive resin is formed in an interlayer connection portion by masking exposure and development, a seed layer is formed by the sputtering method, and plating is performed after patterning of a resist film, thereby forming conductors in vias and wiring, which are interlayer connection portions. A damascene process is typically used in processes using a photosensitive material. In the process, pads and vias are formed in advance by the sputtering method and the electrolytic plating method, and a resin film is formed on the top portions of them. Then, after a stopper layer is formed, polishing is performed by the CMP method, thereby projecting and planarizing connection vias.

Projecting electrodes to be connected to other electronic components are formed on the top layer of a multi-layer circuit board. When the projecting electrodes are connected, a problem such as a short may occur. Hence, it is necessary to form on a surface of the circuit board an insulating film for insulating the projecting electrodes. Generally, an insulating film such as an oxide film is provided between the projecting electrodes Methods for insulating projecting electrodes formed on such a board include a method of forming an inorganic or organic insulating film on the substantially entire surfaces of the board and projecting electrodes, and further performing patterning by, for example, an etching method, laser irradiation, and polishing, thereby exposing the projecting electrodes.

### SUMMARY OF THE INVENTION

A general object of the present invention is to provide an improved and useful circuit board and manufacturing method thereof in which one or more of problems in the prior art are eliminated.

Another and more specific object of the present invention is to provide a manufacturing method of a multi-layer circuit board that does not require, for example, an expensive mask and/or cleaning for removing residue, and allows easy provision of an insulating film between projecting electrodes.

A further object of the present invention is to provide a manufacturing method of a circuit board, including the step of: forming projecting electrodes on a substrate; forming a positive-type photosensitive resin film on the substrate so as to cover the projecting electrodes; exposing a substantially entire surface of the photosensitive film; and melting a surface of the photosensitive film so as to expose the projecting electrodes.

Another object of the present invention is to provide a circuit board having a multi-layer wiring structure including an insulating film, a wiring layer, and electrodes formed on a substrate body, wherein an insulating resin film made of a positive-type photosensitive resin and formed to expose the electrodes is provided in the multi-layer wiring structure.

According to the present invention, by forming a photosensitive resin film so as to cover projecting electrodes formed on a substrate, the thickness of the photosensitive resin film formed on the projecting electrodes is thinner than the thickness of the photosensitive film between the projecting electrodes. Taking advantage of the difference in the thickness of the photosensitive film, the photosensitive resin film is substantially entirely exposed with a predetermined exposure amount without a mask, and the photosensitive resin film is melted by a proper solvent, thereby forming the photosensitive resin film between the projecting electrodes. The predetermined exposure amount is determined based on the ratio of the thickness of the remaining film to the thickness of the applied film. In a structure thus formed, since the projecting electrodes project from the photosensitive resin film that exists between the projecting electrodes, electric connections can be made.

Another object of the present invention is to provide a manufacturing method of a circuit board, wherein the step of exposing is performed at an exposure amount with which amount only a surface portion of the photosensitive film is exposed.

Another object of the present invention is to provide a manufacturing method of a circuit board, wherein the photosensitive film is formed with a thickness substantially the same as a height of the projecting electrodes.

Another object of the present invention is to provide a manufacturing method of a circuit board, wherein, with the step of exposing the projecting electrode, the photosensitive resin film is formed to fill in between the projecting electrodes.

Another object of the present invention is to provide a manufacturing method of a circuit board, wherein, the photosensitive resin film is made of a resin selected from the group consisting of a photosensitive epoxy resin, a photosensitive polyimide resin, a photosensitive poly (benzoxazole) resin, a photosensitive bismaleimide resin, a photosensitive polyquinoline resin, a photosensitive benzo-cyclo-butene resin, a photosensitive cyanate resin, a photosensitive aramid resin, a photosensitive acrylic resin, a photosensitive phenol resin, a photosensitive urea resin, a photosensitive melanin resin, and a photosensitive diallyl phthalate resin.

Another object of the present invention is to provide a circuit board including: a substrate carrying projecting electrodes thereon; and an insulating resin film formed on the substrate such that the projecting electrodes are exposed therefrom, wherein the insulating resin film is made of a positive-type photosensitive resin.

Another object of the present invention is to provide a circuit board, wherein a structure including an insulating film and a wiring layer is formed on the multi-layer wiring structure.

Other objects, features and advantages of the present invention will become more apparent from the following detailed description when read in conjunction with the following drawings.

### BRIEF DESCRIPTION OF THE DRAWINGS

FIG. 1 is a diagram showing the principle of the present invention;

FIG. 2 is another diagram showing the principle of the present invention;

FIG. 3 is a diagram showing a process of an experiment in the case of using a negative-type photosensitive resin;

FIG. 4 is a diagram showing a process of the experiment in the case of using the negative-type photosensitive resin;

FIG. 5 is a diagram showing a process of the experiment in the case of using the negative-type photosensitive resin;

FIG. 6 is a diagram showing a process of the experiment in the case of using the negative-type photosensitive resin;

FIG. 7 is a diagram showing a process of the experiment in the case of using the negative-type photosensitive resin;

FIG. 8 is a graph corresponding to the experiment data of Table 1;

FIG. 9 is a graph corresponding to the experiment data of Table 2;

FIG. 10 is a diagram showing a manufacturing method of a multi-layer circuit board according to a first embodiment of the present invention;

FIG. 11 is a diagram showing the manufacturing method of a multi-layer circuit board according to the first embodiment of the present invention;

FIG. 12 is a diagram showing the manufacturing method of a multi-layer circuit board according to the first embodiment of the present invention;

FIG. 13 is a diagram showing the structure of a multi-layer circuit board according to a second embodiment of the present invention;

FIG. 14 is a diagram showing the structure of a MCM substrate according to a third embodiment of the present invention;

FIG. 15 is a diagram showing the structure of a silicon interposer according to a fourth embodiment of the present invention;

FIG. 16 is a plan view showing the case where a plurality of LSI chips are mounted on a silicon interposer according to a fifth embodiment of the present invention;

FIG. 17 is a diagram showing a manufacturing method of a multi-layer circuit board according to a sixth embodiment of the present invention;

FIG. 18 is a diagram showing the manufacturing method of a multi-layer circuit board according to the sixth embodiment of the present invention;

FIG. 19 is a diagram showing the manufacturing method of a multi-layer circuit board according to the sixth embodiment of the present invention;

FIG. 20 is a diagram showing the manufacturing method of a multi-layer circuit board according to the sixth embodiment of the present invention;

FIG. 21 is a diagram showing the manufacturing method of a multi-layer circuit board according to the sixth embodiment of the present invention;

FIG. 22 is a diagram showing the manufacturing method of a multi-layer circuit board according to the sixth embodiment of the present invention; and

FIG. 23 is a diagram showing the manufacturing method of a multi-layer circuit board according to the sixth embodiment of the present invention.

### DETAILED DESCRIPTION OF THE PREFERRED EMBODIMENTS

In the case where an inorganic insulating film is formed between the projecting electrodes by an etching method, since a CVD process, a sputtering process, or a dry etching process, each requiring a vacuum process, is used, throughput is reduced. In addition, it is necessary to perform patterning of a resist film before etching, and a masking process therefor is required. Since the masking process includes a mask alignment process and uses a contact exposure method, the mask tends to be damaged easily. Further, it is necessary to prepare a mask every time the layout of the projecting electrodes is varied, which leads to an increase in costs. Additionally, in the case where the height of the projecting electrodes is several tens of micrometers or more, there is a problem of, for example, degradation of insulation reliability due to insufficient provision of an insulating film at corner portions of bottom portions of sidewalls of the projecting electrodes.

On the other hand, a technique has been proposed in which an organic insulating film is formed on a surface of a substrate, and openings are formed therein by using a laser beam. In this case, however, the processing time becomes longer in proportion to the number of openings formed in the substrate. In addition, the minimum diameter that can be processed is approximately 50 μmφ, due to beam diameter constraints. Thus, it is difficult or impossible to form microscopic openings. Further, since carbonaceous residue of resin is left in the bottom portions of openings, there is a problem in that a chemical process is required after the openings are formed. In the case where polishing is used, scratches and chips resulting from polishing tend to be formed easily, and the process costs are high. There is a further problem in that narrow selections are offered for resin, since strength and adhesion that are high enough to bear polishing are required for the resin.

(Principle)

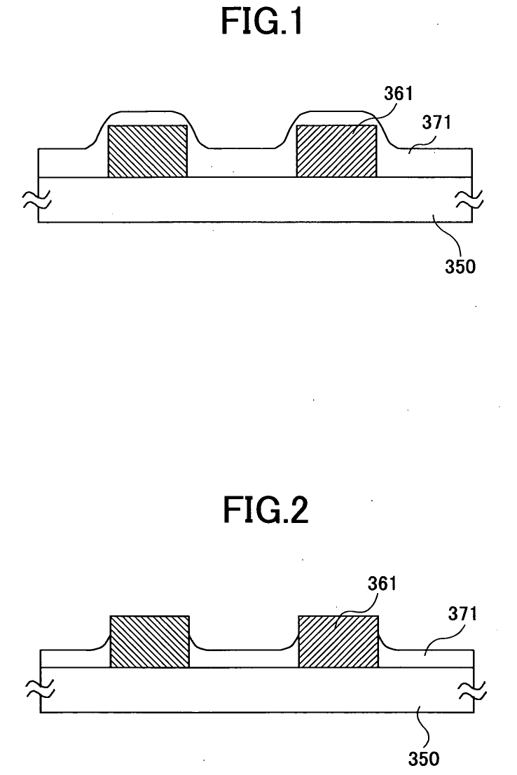

FIGS. 1 and 2 are diagrams showing the principle of the present invention.

In the present invention, as shown in FIG. 1, after forming a photosensitive resin 371 on a substrate 350 so as to cover projecting electrodes 361 on the substrate 350, the substantially entire surface of the photosensitive resin 371 is exposed so as to melt the surface of the photosensitive resin 371, thereby exposing the projecting electrodes 361 and providing the photosensitive resin 371, serving as an insulating layer, between the projecting electrodes 361 as shown in FIG. 2.

On this occasion, in the present invention, in the case where the photosensitive resin 371 is formed by an application process on the substrate 350 such that the photosensitive resin 371 covers the projecting electrodes 361, by taking advantage of the fact that the thickness of the photosensitive resin 371 on the projecting electrodes 361 substantially corresponds to the ratio of the thickness of the photosensitive resin 371 applied on the projecting electrodes 361 on the substrate 350 to the height of the projecting electrodes 361, the thickness of the photosensitive resin 371 being slightly reduced by exposure and development processes, so as to expose the projecting electrodes 361 from the photosensitive resin 371.

Accordingly, upon implementing the present invention, the exposure amount of a photosensitive resin is important. Thus, a description is given of the results of experiments on the relationship between the exposure amount and the ratio of a remaining film of a photosensitive resin, which experiments were performed by the inventors of the present invention.

In the experiments, ZFPI-5500, which is a polyimide material manufactured by ZEON Corporation, is used as a negative-type photosensitive resin, and RN-902, which is a polyimide material manufactured by Nissan Chemical Industries, Ltd., as a positive-type photosensitive resin.

First, a description is given of the method of the experiment performed by using ZFPI-5500, which is a polyimide material manufactured by ZEON Corporation, as a negative-type photosensitive resin.

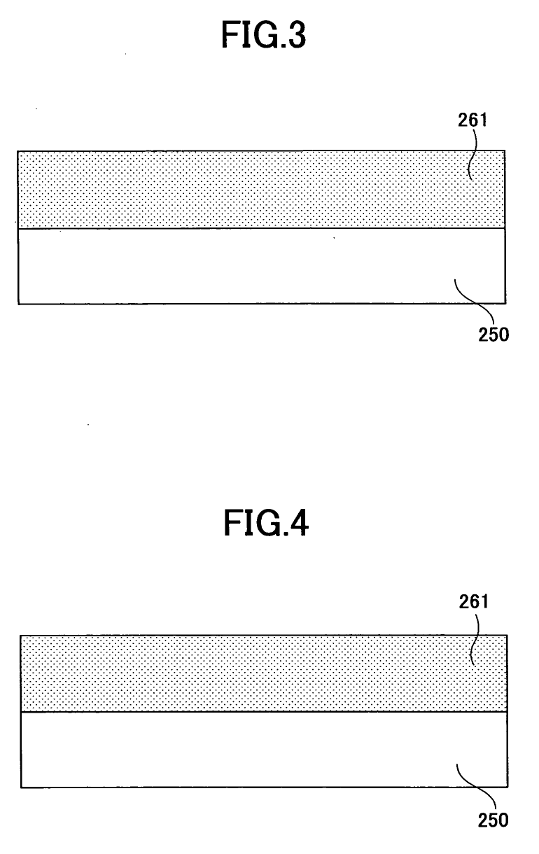

FIGS. 3 through 7 are diagrams showing processes of the experiment in the case of using the negative-type photosensitive resin.

As shown in FIG. 3, ZFPI-5500 is applied as a negative-type photosensitive polyimide film 261 on a Si substrate 250 under the conditions that the revolutions per minute is 2100 rpm and the processing time is 30 seconds.

Next, pre-drying of the negative-type photosensitive polyimide film 261 is performed in a clean oven (not shown) under the conditions that the temperature is 60° C. and the processing time is 30 minutes (see FIG. 4).

Next, as shown in FIG. 5, an exposure and development process of the negative-type photosensitive polyimide film 261 is performed. The exposure conditions (exposure amounts) include 11 conditions, i.e., 400 mJ, 240 mJ, 200 mJ, 160 mJ, 140 mJ, 120 mJ, 100 mJ, 88 mJ, 80 mJ, 72 mJ and 64 mJ.

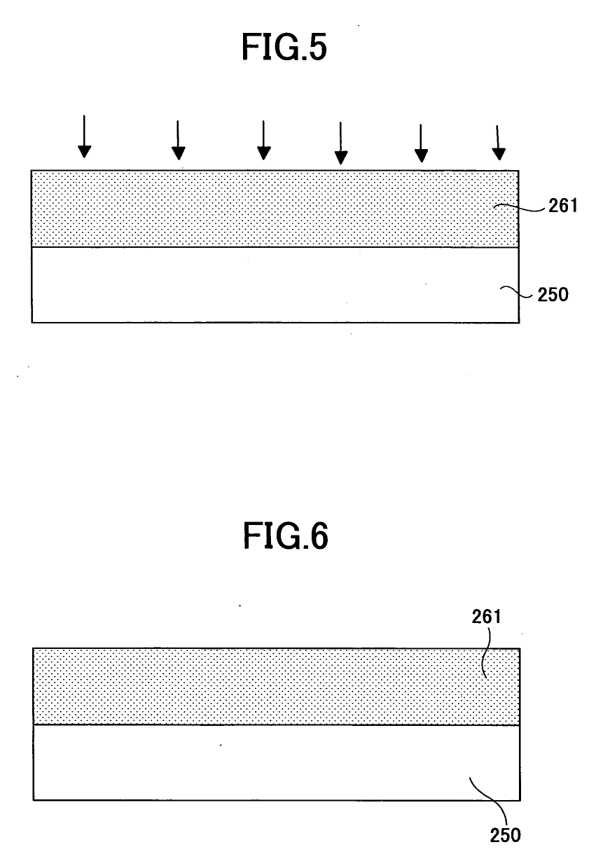

Next, as shown in FIG. 6, a baking process is performed in a nitrogen atmosphere under the conditions that the temperature is 400° C. and the processing time is two hours.

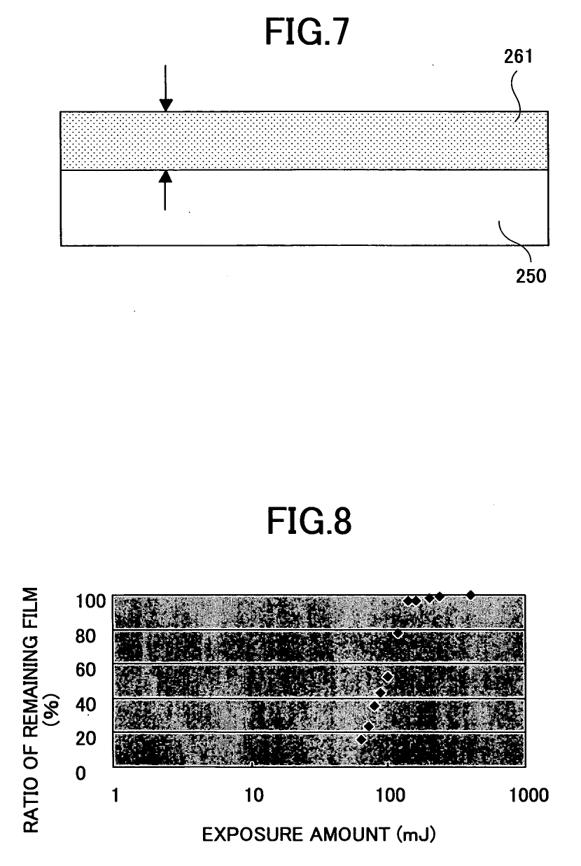

Then, as shown in FIG. 7, the thickness of the negative-type photosensitive polyimide film 261 is measured, and the ratio of the remaining film (%) is calculated based on the thickness data.

A description is given of a calculation method of the ratio of the remaining film (%).

In the case where the negative-type photosensitive polyimide film 261 is exposed with an exposure amount of 400 mJ, there is no difference in the thickness of the negative-type photosensitive polyimide film 261 before exposure and after development. That is, in the case of the negative-type photosensitive polyimide film 261, only when exposure is performed with an exposure amount less than 400 mJ, the negative-type photosensitive polyimide film 261 is developed in the developing process.

Accordingly, in this experiment, it is assumed that the ratio of the remaining film (%) is indicated by the ratio of a thickness B at the time when a baking process is performed after exposing under another exposure condition to a thickness A of the negative-type photosensitive polyimide film 261 subjected to the baking process after exposing with the exposure amount of 400 mJ. That is, the ratio of the remaining film for the thickness A is 100%. Thus, when the thickness A is 10 μm and the thickness B is 8 μm, the ratio of the remaining film (%) is 80%.

A description is given of the results of the experiment using ZFPI-5500, which is a polyimide material manufactured by ZEON Corporation in Japan, as a negative-type photosensitive resin.

Table 1 shows the results of the experiments in the cases where the negative-type photosensitive polyimide film was used. FIG. 8 is a graph showing the experiment data of Table 1.

TABLE 1

| | Thickness of Negative-type | Ratio of |
|---|---|---|
| Exposure Amount | Photosensitive Polyimide | Remaining |
| (mJ) | after Baking (μm) | Film (%) |
| 400 | 5.1865 | 100 |
| 240 | 5.1403 | 99 |
| 200 | 5.0884 | 98 |
| 160 | 5.0275 | 97 |
| 140 | 5.0091 | 97 |
| 120 | 4.0251 | 78 |
| 100 | 2.7142 | 52 |
| 88 | 2.2252 | 43 |
| 80 | 1.8500 | 36 |
| 72 | 1.2331 | 24 |
| 64 | 0.8183 | 16 |

Referring to Table 1, it is found that, in the case of the negative-type photosensitive polyimide film 261, as the exposure amount is decreased, the ratio of the remaining film (%) is also decreased.

Referring to FIGS. 3 through 7, a description is given of the method of the experiment performed by using RN-902, which is a polyimide material manufactured by Nissan Chemical Industries, Ltd., as a positive-type photosensitive resin.

It should be noted that the following description is given by replacing the negative-type photosensitive polyimide film 261 in FIGS. 3 through 7 with a positive-type photosensitive polyimide film.

Referring to FIG. 3, instead of the negative-type photosensitive polyimide film 261, RN-902, which is a positive-type photosensitive polyimide film, is applied on the Si substrate 250 under the conditions that the revolutions per minute is 3500 rpm and the processing time is 20 seconds.

Next, pre-drying of the positive-type photosensitive polyimide film is performed in a hot plate (not shown) under the conditions that the temperature is 80° C. and the processing time is 20 minutes (see FIG. 4).

Next, as shown in FIG. 5, an exposure and development process of the positive-type photosensitive polyimide film is performed. The exposure conditions (exposure amounts) include 11 conditions, i.e., 1 mJ, 10 mJ, 40 mJ, 50 mJ, 70 mJ, 100 mJ, 200 mJ, 400 mJ, 500 mJ, 700 mJ and 1000 mJ.

Next, as shown in FIG. 6, a baking process is performed in a nitrogen atmosphere under the conditions that the temperature is 350° C. and the processing time is 30 minutes.

Then, as shown in FIG. 7, the thickness of the positive-type photosensitive polyimide film is measured, and the ratio of the remaining film (%) is calculated based on the data of the thickness.

A description is given of a calculation method of the ratio of the remaining film (%).

In the case where the positive-type photosensitive polyimide film is exposed with an exposure amount of 1 mJ, there is no difference in the thickness of the negative-type photosensitive polyimide film before exposure and after development. That is, in the case of the positive-type photosensitive polyimide film 261, only when exposure is performed with an exposure amount more than 1 mJ, the positive-type photosensitive polyimide film is developed in the developing process.

Accordingly, in this experiment, it is assumed that the ratio of the remaining film (%) is indicated by the ratio of a thickness B at the time when a baking process is performed after exposing under another exposure condition to a thickness A of the positive-type photosensitive polyimide film subjected to the baking process after exposing with the exposure amount of 1 mJ. That is, the ratio of the remaining film for the thickness A is 100%. Thus, when the thickness A is 10 μm and the thickness B is 8 μm, the ratio of the remaining film (%) is 80%.

A description is given of the results of the experiments using RN-902, which is a polyimide material manufactured by Nissan Chemical Industries, Ltd., as a positive-type photosensitive resin.

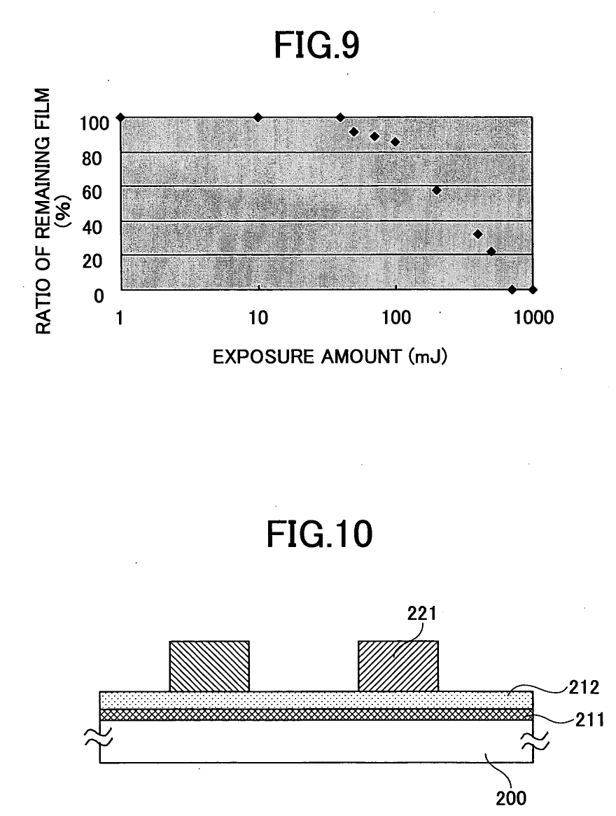

Table 2 shows the results of the experiments in the cases where the positive-type photosensitive polyimide film was used. FIG. 9 is a graph showing the experiment data of Table 2.

Referring to Table 2, it is found that, in the case of the positive-type photosensitive polyimide film, as the exposure amount is increased, the ratio of the remaining film (%) is decreased.

In the case where the photosensitive resin of this experiment is deposited on projecting electrodes formed on a multi-layer circuit board, the thickness of the photosensitive resin formed on the projecting electrodes is less than the thickness of the photosensitive resin formed between the projecting electrodes. Taking advantage of the difference in the thickness of the photosensitive resin, it is possible to readily provide an insulating film between the projecting electrodes and exposing the projecting electrodes by exposing and thereafter developing the substantially entire photosensitive resin formed on the substrate.

TABLE 2

| | Thickness of Negative-type | Ratio of |
|---|---|---|
| Exposure Amount | Photosensitive Polyimide | Remaining |
| (mJ) | after Baking (μm) | Film (%) |
| 1 | 5.1050 | 100 |
| 10 | 5.0884 | 100 |
| 40 | 5.0864 | 100 |
| 50 | 4.6556 | 91 |
| 70 | 4.5253 | 89 |
| 100 | 4.3550 | 85 |
| 200 | 2.9358 | 58 |
| 400 | 1.6353 | 32 |
| 50 | 1.1252 | 22 |
| 700 | 0.0000 | 0 |
| 1000 | 0.0000 | 0 |

A description is given below of embodiments of the present invention with reference to the drawings.

### First Embodiment

FIGS. 10 through 12 show a manufacturing method of a multi-layer circuit board according to a first embodiment of the present invention, wherein ZFPI-5500, which is a negative-type photosensitive polyimide film, is provided between projecting electrodes.

As shown in FIG. 10, a Cr film 211 is formed on a Si substrate 200 with a thickness of 80 nm. After further forming a Cu film 212 as a seed layer with a thickness of 500 nm, Cu projecting electrodes 221, having the height of 20 μm and the diameter of 50 μm, are formed on the Cu film 212 by an electrolytic plating method.

Next, ZFPI-5500, which is a negative-type photosensitive polyimide film, is applied on the projecting electrodes 221 with a thickness of approximately 5 μm so as to cover the Cu film 212, under the conditions that the revolutions per minute is 2100 rpm and the processing time is 30 seconds. In addition, as for methods for applying a negative-type photosensitive polyimide film, it is possible to apply a negative-type photosensitive polyimide film by any method of laminating, spin-coating and squeeze print application.

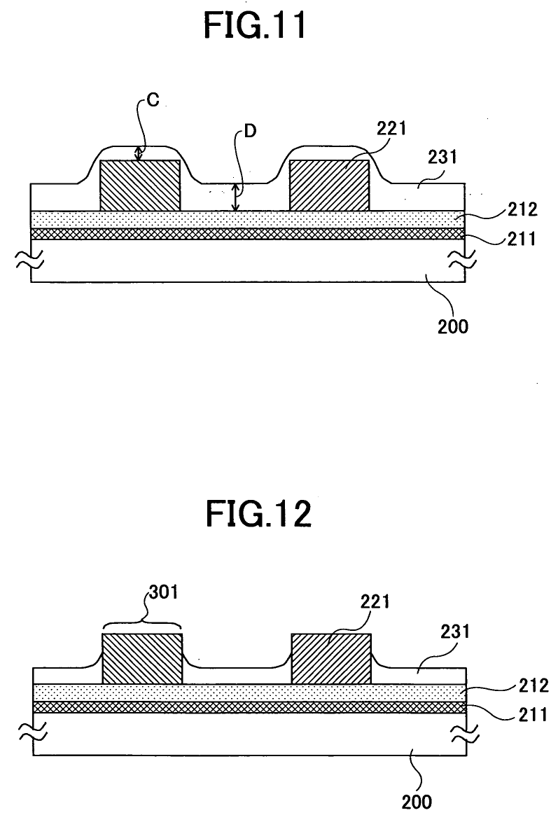

Then, pre-drying of the negative-type photosensitive polyimide film 231 is performed in a clean oven under the conditions that the temperature is 60° C. and the processing time is 30 minutes, which results in a structure as shown in FIG. 11. A thickness C of the negative-type photosensitive polyimide film 231 on the Cu projecting electrodes 221 was 4 μm. Additionally, a thickness D of the negative-type photosensitive polyimide film 231 between the Cu projecting electrodes 221 was 10 μm.

It should be noted that, in the present invention, the thickness of the resin film may be formed substantially the same as the height of the electrodes. In this case, the ratio of the height of the electrodes to the thickness of the resin film is approximately 1:1.

In the aforementioned manner, in the case where the photosensitive resin is applied in a shape including concavity and convexity, the thickness of the photosensitive resin in convex portions is thin compared to that in concave portions. Taking advantage of the difference in the thickness of the photosensitive resin, by exposing and developing the substantially entire photosensitive resin formed on the projecting electrodes and thereby removing the photosensitive resin on the projecting electrodes, it is possible to readily provide the insulating film between the projecting electrodes and expose the projecting electrodes for forming bumps thereon.

Accordingly, in order to form bumps on the Cu projecting electrodes 221 on the Si substrate 200 of this example, it is necessary to remove the negative-type photosensitive polyimide film, having a thickness of 4 μm, formed on the Cu projecting electrodes so as to expose the Cu projecting electrodes.

Thus, the surface of the negative-type photosensitive polyimide film 231 is exposed at an exposure amount of 110 mJ (see Table 1), which amount is necessary to remove the negative-type photosensitive polyimide film 231 formed on the Cu projecting electrodes 221 and having a thickness of 4 μm, by using an exposure apparatus.

Next, a developing process is performed, and then a baking process is performed in a nitrogen atmosphere on the conditions that the temperature is 400° C. and the processing time is two hours. Thereby, as shown in FIG. 12, the negative-type photosensitive polyimide film 231 is provided between the Cu projecting electrodes 221, and top portions 301 of the Cu projecting electrodes 221 are exposed.

By applying such a manufacturing method, it becomes unnecessary to prepare a mask required in the case of using an etching method for processing and to perform a chemical process for removing residue required in the case of using a laser beam. Hence, it is possible to readily expose surfaces of projecting electrodes at low cost and provide a negative-type photosensitive polyimide film between the projecting electrodes. Accordingly, it is possible to insulate the projecting electrodes from each other, and avoid problems such as a short between the projecting electrodes.

Additionally, in this embodiment, a negative-type photosensitive polyimide film is applied as a photosensitive resin. However, with the use of a positive-type photosensitive polyimide film, it is also possible to readily expose surfaces of projecting electrodes and provide a positive-type photosensitive polyimide film between the projecting electrodes.

### Second Embodiment

The manufacturing method of a multi-layer circuit board according to first embodiment of the present invention may be combined with a build-up substrate or a LSI chip.

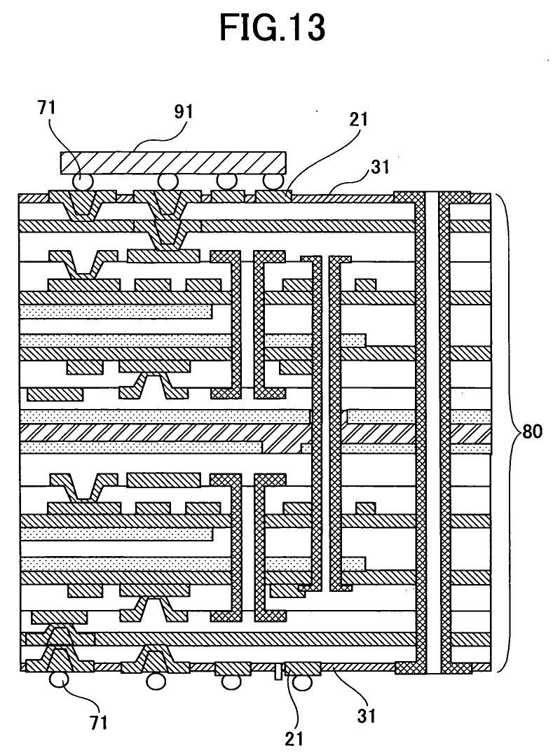

FIG. 13 shows the structure of a multi-layer circuit board according to a second embodiment of the present invention.

As shown in FIG. 13, projecting electrodes 21 are provided on the principal surfaces of the top and bottom of a multi-layer build-up substrate 80, and bumps 71 are formed on the projecting electrodes 21. Additionally, a LSI chip 91 is connected to the projecting electrodes 21 via the bumps 71 on the principal surface of the top of the multi-layer build-up substrate 80.

The multi-layer build-up substrate 80 of FIG. 13 includes a structure in which a number of wiring layers are stacked. Further, it can be seen that one wiring layer is connected to another wiring layer through via contacts.

A photosensitive resin 31 is provided on the principal surfaces of the top and bottom of the multi-layer build-up substrate 80 so as to cover the portions between the projecting electrodes 21, thereby insulating the projecting electrodes 21 from each other. Thereby, it is possible to insulate between projecting electrodes and avoid problems such as a short between the projecting electrodes. In the aforementioned manner, the present invention may be applied when, for example, mounting a LSI chip on a build-up substrate.

### Third Embodiment

The manufacturing method of a multi-layer circuit board according to the first embodiment of the present invention may be combined with, for example, a build-up layer, a LSI chip and a heat sink.

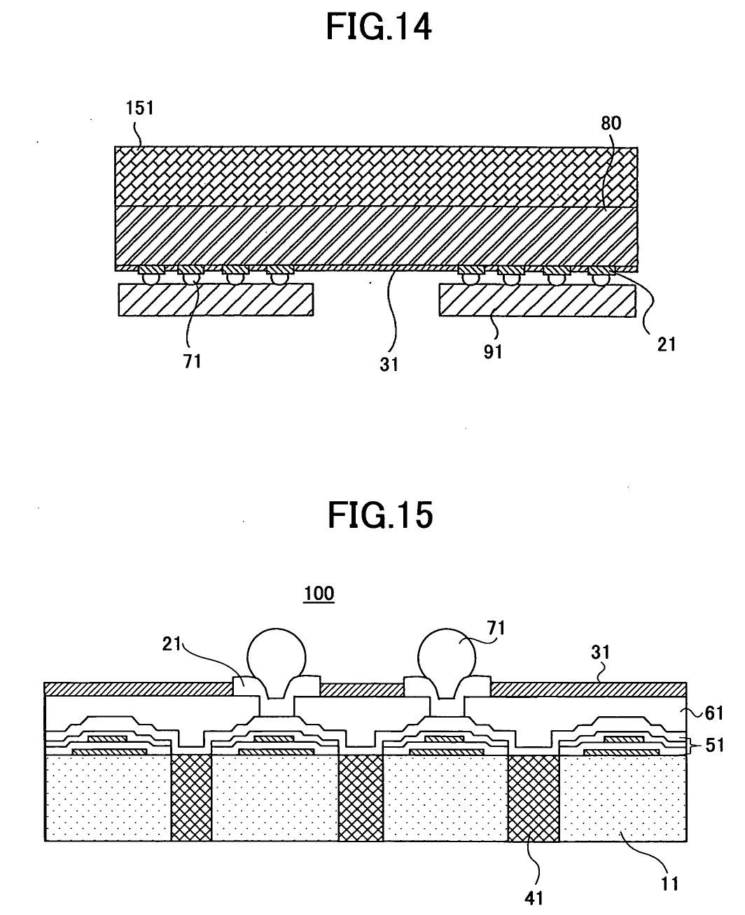

FIG. 14 shows the structure of a MCM substrate according to a third embodiment of the present invention.

As shown in FIG. 14, a heat sink 151 is provided on one surface of the multi-layer build-up switch unit 80 and a plurality of LSI chips is provided on the other surface of the multi-layer build-up switch unit 80 via the bumps 71 formed on the projecting electrodes 21. In addition, the photosensitive resin 31 is provided between the projecting electrodes 21, thereby insulating the projecting electrodes 21 from each other. Accordingly, it is possible to insulate between the projecting electrodes 21 and avoid problems such as a short between the projecting electrodes 21. In the aforementioned manner, the present invention may be applied to a MCM (Multi Chip Module) substrate.

### Fourth Embodiment

The first embodiment of the manufacturing method of a multi-layer circuit board according to the present invention may be applied to a silicon interposer.

FIG. 15 shows the structure of a silicon interposer according to a fourth embodiment of the present invention.

As shown in FIG. 15, through vias 41 are provided inside a Si substrate 11, and ferroelectric capacitors 51 are formed on the Si substrate 11. An insulating film 61 is formed on the ferroelectric capacitors 51, and the projecting electrodes 21 are provided inside and on the insulating film 61. Bumps 71 are formed on the upper portions of the projecting electrodes 21, and the photosensitive resin 31 is provided between the projecting electrodes 21, thereby insulating the projecting electrodes 21 from each other. Accordingly, it is possible to insulate projecting electrodes from each other and avoid problems such as a short between the projecting electrodes.

In the aforementioned manner, the present invention may be applied to a silicon interposer.

### Fifth Embodiment

A plurality of LSI chips may be mounted on an interposer, which is the fourth embodiment of the manufacturing method of a multi-layer circuit board according to the present invention.

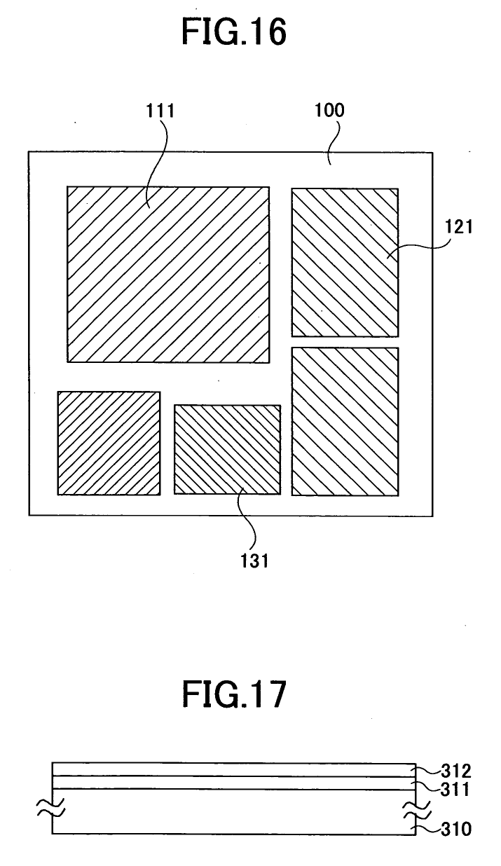

FIG. 16 is a plan view in the case where a plurality of LSI chips is mounted on a silicon interposer according to a fifth embodiment of the present invention.

As shown in FIG. 16, logic and SRAM 111, a flash memory 121 and an analog circuit 131 may be mounted on a silicon interposer 100.

It should be noted that LSI chips that may be mounted on a silicon interposer are not limited to the above-mentioned LSI chips.

### Sixth Embodiment

FIGS. 17 through 23 show a manufacturing method of a multi-layer wiring structure according to a sixth embodiment of the present invention, wherein ZFPI-5500, which is a negative-type photosensitive polyimide film, is provided in a stacked via structure.

As shown in FIG. 17, a Cr film 311 is formed on a substrate 310 with a thickness of 80 nm, and a Cu film 312 is further formed on the Cr film 311 as a seed layer with a thickness of 500 nm.

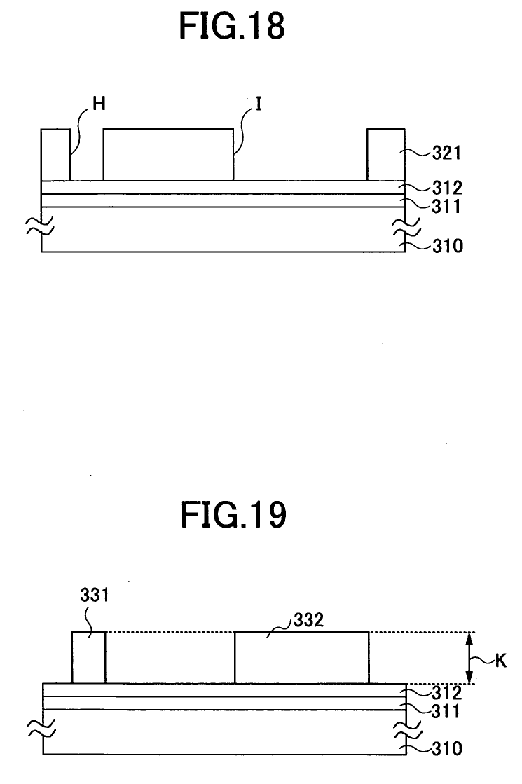

After applying a resist film 321 on the Cu film 312, pre-curing is performed in a clean oven for 30 minutes at a temperature of 80° C. Next, by using a mask (not shown) for forming wiring and pads, development is performed after exposure on the condition of 400 mJ/cm², thereby forming openings H and openings I such as shown in FIG. 18. The openings H are openings for forming a wiring pattern and the width of each of the openings H is 10 μm. The openings I are openings for forming pads and the width of each of the openings I is 80 μm. Subsequently, copper sulfate plating is performed to form a Cu film inside the openings H and I, and thereafter the resist film 321 is removed to form a Cu wiring pattern 331 and Cu pads 332 as shown in FIG. 19. The height K of the Cu wiring pattern 331 and the Cu pads 332 is approximately 5 μm.

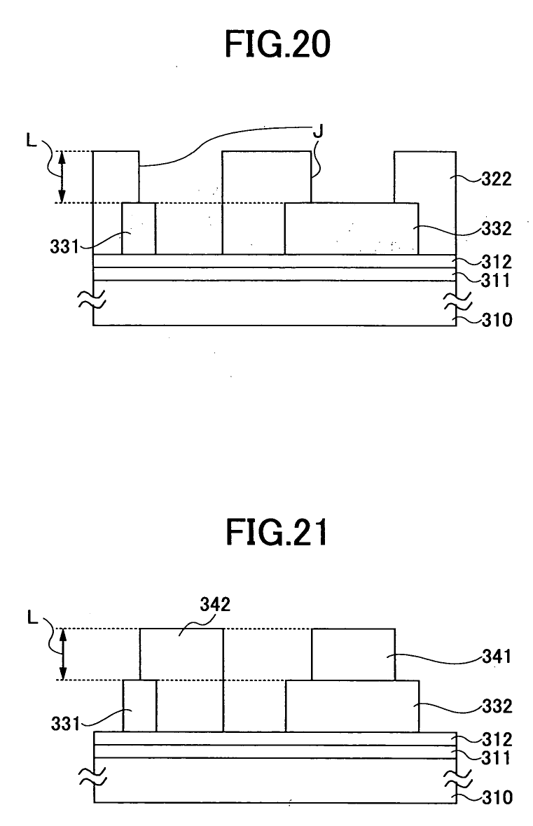

Next, after applying a resist film on the Cu wiring pattern 331, the Cu pads 332 and the Cu film 312, pre-curing was performed in a clean oven on the conditions that the temperature is 60° C. and the processing time is 30 minutes. Next, by using a via forming mask (not shown), development is performed after exposure at the condition of 400 mJ/cm², thereby forming an opening J as shown in FIG. 20. Subsequently, copper sulfate plating is performed to form a Cu film inside the opening J, and thereafter the resist film 322 is removed to form Cu via patterns 341 and 342 as shown in FIG. 21. The height L of the Cu via patterns 341 and 342 is approximately 5 μm.

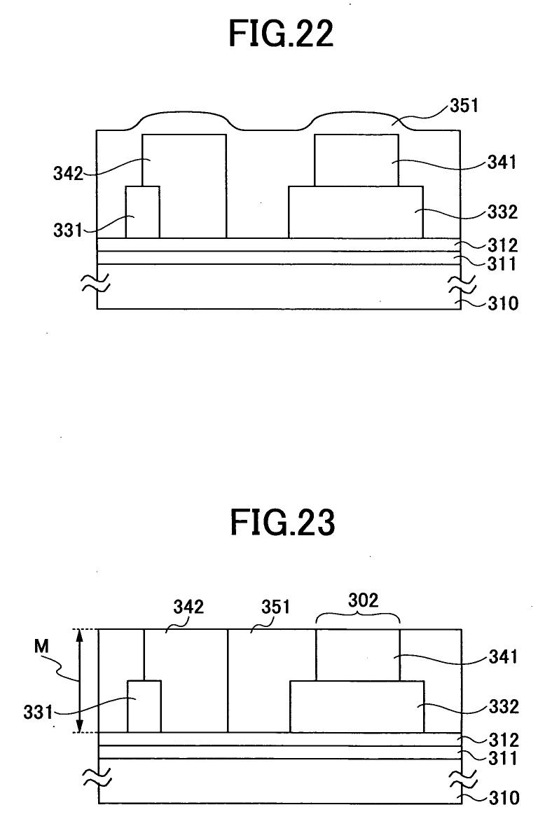

Subsequently, as shown in FIG. 22, ZFPI-5500, which is a negative-type photosensitive polyimide film 351, is spin-coated on the conditions that the number of revolutions is 1000 rpm and the processing time is 30 seconds. Thereafter, pre-curing is performed in a clean oven on the conditions that the temperature is 60° C. and the processing time is 30 minutes.

Next, after exposing the surface of the negative-type photosensitive polyimide film 351 on the condition of 200 mJ/cm², spray development is performed by using a developer ZPID. Then, a rinsing process is performed for two minutes by using isopropanol solution, thereby exposing top portions of the vias as shown in FIG. 23. Curing of the negative-type photosensitive polyimide film 351 is performed in a nitrogen atmosphere on the conditions that the temperature is 400° C. and the processing time is 120 minutes. A thickness M of the negative-type photosensitive polyimide film 351 after curing was 9.8 μm.

As a result of forming the second through tenth layers in a similar manner, continuity in the stacked vias and insulation performance between the stacked vias were confirmed, and a multi-layer wiring structure having good wiring reliability in the Cu wiring and the Cu vias was obtained.

According to the present invention, by taking advantage of the fact that, when a photosensitive resin is applied on a substantially entire surface of a substrate having projecting electrodes formed thereon, the thickness of the photosensitive resin on the projecting electrodes is formed thinner than that between the projecting electrodes, an exposure process and a developing process are performed on the substantially entire surface after application of the photosensitive resin as a method for insulating the projecting electrodes formed on the multi-layer circuit board from each other and forming bumps on the top portions of the projecting electrodes. Hence, it is possible to insulate projecting electrodes from each other by providing a photosensitive resin between the projecting electrodes, and expose the top portions of the projecting electrodes so as to form bumps thereon.

The present invention is not limited to the specifically disclosed embodiments, and variations and modifications may be made without departing from the scope of the present invention.

1. A manufacturing method of a circuit board, comprising the steps of:
forming projecting electrodes on a substrate;
forming a positive-type photosensitive resin film on the substrate so as to cover the projecting electrodes;
exposing a substantially entire surface of the photosensitive film; and
melting the surface of the photosensitive film so as to expose the projecting electrodes.

2. The manufacturing method as claimed in claim 1, wherein the step of exposing is performed at an exposure amount with which amount only a surface portion of the photosensitive film is exposed.

3. The manufacturing method as claimed in claim 1, wherein the photosensitive film is formed with a thickness substantially the same as a height of the projecting electrodes.

4. The manufacturing method as claimed in claim 1, wherein, with the step of exposing the projecting electrode, the photosensitive resin film is formed to fill in between the projecting electrodes.

5. The manufacturing method as claimed in claim 1, wherein the photosensitive resin film is made of a resin selected from the group consisting of a photosensitive epoxy resin, a photosensitive polyimide resin, a photosensitive poly(benzoxazole) resin, a photosensitive bismaleimide resin, a photosensitive polyquinoline resin, a photosensitie benzo-cyclo-butene resin, a photosensitive cyanate resin, a photosensitive aramid resin, a photosensitive acrylic resin, a photosensitive phenol resin, a photosensitive urea resin, a photosensitive melanin resin, and a photosensitive diallyl phthalate resin.

6. A circuit board, comprising:
a substrate carrying projecting electrodes thereon; and
an insulating resin film formed on the substrate such that the projecting electrodes are exposed therefrom;
wherein the insulating resin film is made of a positive-type photosensitive resin film.

7. The circuit board as claimed in claim 6,
wherein the projecting electrodes include:
first projecting electrodes formed on a first principal surface of the substrate; and
second projecting electrodes formed on a second principal surface opposing to the first principal surface;
wherein the positive-type photosensitive film includes:
a first photosensitive resin film formed on the first principal surface such that the first projecting electrodes are exposed therefrom; and
a second photosensitive resin film formed on the second principal surface such that the second projecting electrodes are exposed therefrom.

8. The circuit board as claimed in claim 6, wherein the substrate includes a throughhole extending from the first principal surface to the second principal surface and a conductor plug provided in the throughhole and extending from the first principal surface to the second principal surface.

9. A circuit board having a multi-layer wiring structure including an insulating film, a wiring layer and electrodes formed on a substrate body,
wherein an insulating resin film made of a positive-type photosensitive resin and formed to expose the electrodes is provided in the multi-layer wiring structure.

10. The circuit board as claimed in claim 9, wherein a structure in which an insulating film and a wiring layer are stacked is formed on the multi-layer wiring structure.

11. The circuit board as claimed in claim 9, wherein the circuit board carries a semiconductor chip thereon.

12. The circuit board as claimed in claim 9, wherein the circuit board carries a plurality of semiconductor chips thereon.
